(19) United States
(12) Patent Application Publication
(10) Pub. No.: US 2013/0009031 A1
(43) Pub. Date: Jan. 10, 2013

(54) SUPPORT MECHANISM FOR ELECTRONIC DEVICE

(75) Inventors: QUAN-CHANG CHENG, Shenzhen City (CN); CONG-BING ZHOU, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/272,267

(22) Filed: Oct. 13, 2011

(30) Foreign Application Priority Data
Jul. 5, 2011 (CN) 201110185988.X

(51) Int. Cl. H05K 7/00

(52) U.S. Cl. 248/371

(57) ABSTRACT

A support mechanism is used for supporting an electronic device on a support surface. The support mechanism includes a first support member for supporting the electronic device, a second support member connected to the first support member for supporting the first support member; and an adjusting assembly secured to the second support member and used for adjusting the height of the second support member relative to the support surface.

### BACKGROUND

1. Technical Field

The present disclosure related to support mechanisms and, particularly, to a support mechanism for supporting an electronic device.

2. Description of Related Art

Many hand-held electronic devices, such as mobile phones or tablet computers, are now commonly used and supported by some included mechanism in an upright position on a support surface. However, many support mechanisms are not adjustable and so may not provide the best viewing angle in various circumstances for different users.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of a support mechanism for supporting an electronic device in accordance with an embodiment.

FIG. 2 is a disassembled view of the support mechanism of FIG. 1.

FIG. 3 is partially assembled view of the support mechanism of FIG. 1.

### DETAILED DESCRIPTION

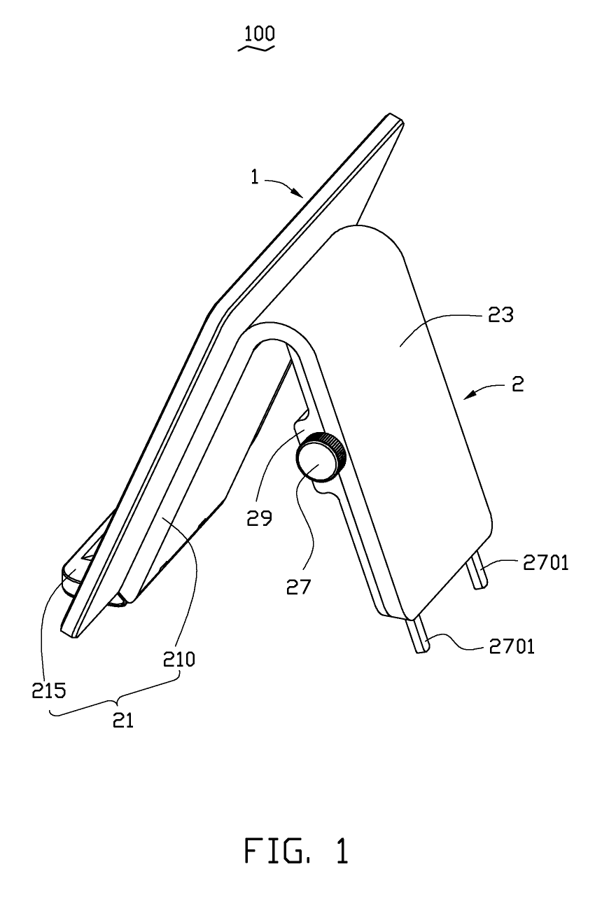

Referring to FIG. 1, an apparatus 100 includes an electronic device 1 and a support mechanism 2 for supporting the electronic device 1. In some embodiments, the electronic device 1 may be a mobile phone, a tablet computer, or a music player. The support mechanism 2 is generally an inverted V-shaped piece with adjustably extendable legs for supporting the device 1 at different angles relative to a supporting surface. The front of the V-shaped piece is a first support member 21 for holding the electronic device 1, the back of the V-shaped piece is a second support member 23 having an adjusting assembly 27 for adjusting the distance between the second support member 23 and a support surface, and a restricting member 29 connected to the second support member 23.

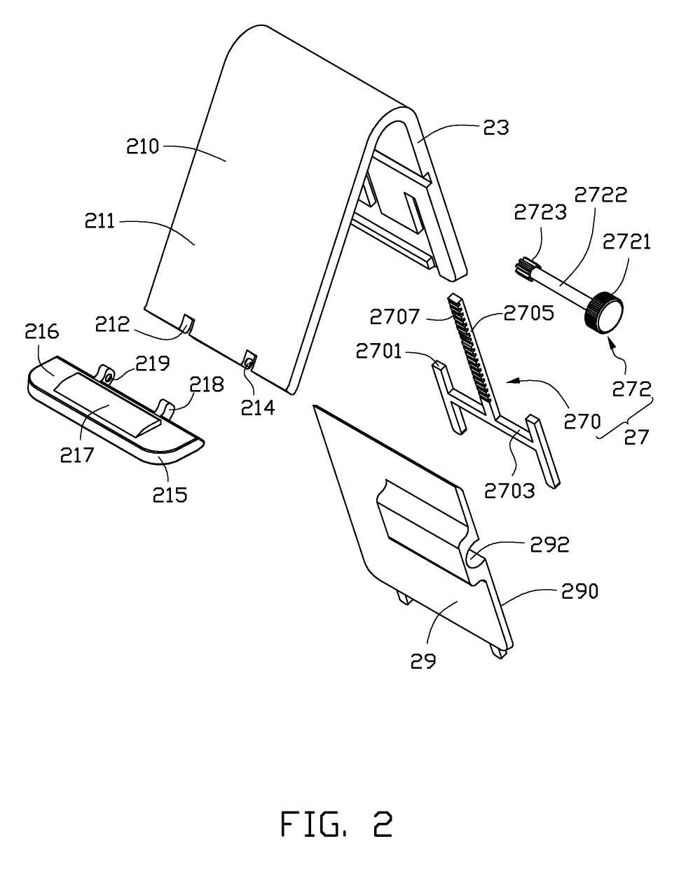

Referring to FIG. 2, the first support member 21 includes a main body 210 and a base 215 rotatably connected to the main body 210. The main body 210 is substantially rectangular, and includes a contacting surface 211 corresponding to a back portion of the electronic device 1. The free end of the main body 210 defines two openings 212. Two shafts 214 are respectively disposed in the two openings 212. The shafts 214 respectively protrude from sidewalls (not labeled) of each opening 212. The base 215 is rotatably connected to the free end of the main body 210 and cooperates with the main body 210 to support the electronic device 1. The base 215 includes a seat 216 for supporting the electronic device 1, a block 217 protruding from the seat 216, and two protrusions 218 protruding from a rim of the seat 216. The protrusions 218 respectively correspond to the openings 212, and each protrusion 218 defines a blind hole 219 for rotatably receiving the corresponding shaft 214. A clearance is defined between the block 217 and the contacting surface 211 to hold an end of the electronic device 1.

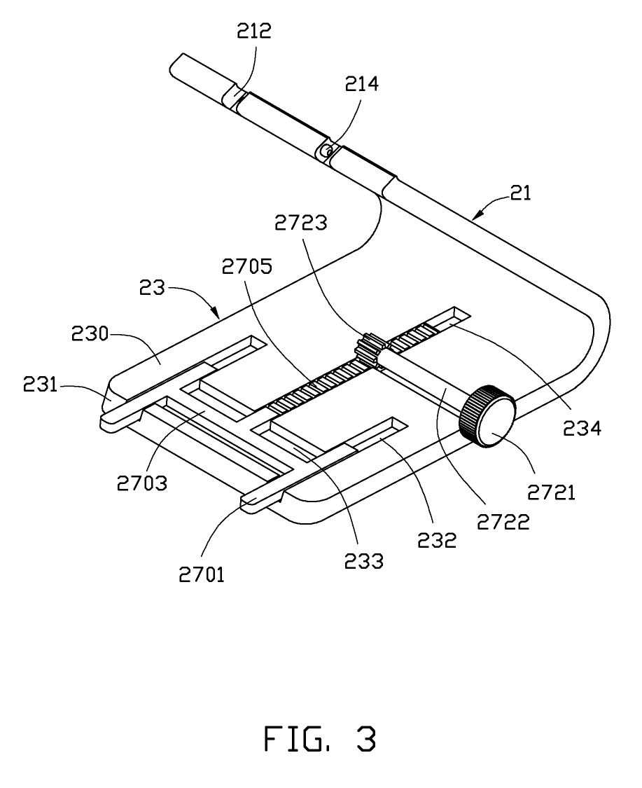

Referring also to FIG. 3, the second support member 23 integrally extends from the main body 210 to form an inverted V shaped piece. The second support member 23 is substantially rectangular, and includes an assembly surface 230 facing the main body 210 and a sidewall 231 substantially perpendicular to the assembly surface 230. The assembly surface 230 is recessed to define two parallel first sliding slots 232, a second sliding slot 233, and a third sliding slot 234. Each first sliding slot 232 is substantially perpendicular to the sidewall 231 and is open at an end communication with the sidewall 231. The second slot 233 communicates with the two first sliding slots 232 and is substantially perpendicular to the first sliding slots 232. The third slot 234 communicates with the second sliding slot 233 and is substantially parallel with and sandwiched between the first sliding slots 232. In the illustrated embodiment, the second sliding slot 233 is arranged adjacent to the assembly surface 230, and the third sliding slot 234 is longer than either of the first slot 232.

The adjusting assembly 27 includes a sliding member 270 and a driving member 272. The sliding member 270 includes two paralleled extendable legs 2701 corresponding to the two first slots 232, a connection post 2703 for connecting the two extendable legs 2701 to the adjusting assembly 27, and a toothed post 2705 connected to the connection post 2703 and corresponding to the third slot 234. The extendable legs 2701, the connection post 2703, and the post 2705 are coplanar. The toothed post 2705 defines a toothed surface 2707. Each extendable leg 2701 is capable of sliding in a corresponding one of the first slots 232 to partly extend out of the second support member 23. The connection post 2703 is capable of sliding in the second slot 233. The toothed post 2705 is capable of sliding in the third slot 234. The width of the connection post 2703 is less than that of the second sliding slot 233, such that the extendable legs 2701 can slide in the corresponding slots 232 to extend through the sidewall 231 to extend out of the second support member 23 when the toothed post 2705 is driven to slide in the third sliding slot 234. As a result, the length of the part of each extendable leg 2701 extending out of the second support member 23 is adjustable.

The driving member 272 includes a knob 2721, a gear member 2723 corresponding to the toothed post 2705, and a connection shaft 2722 for connecting the knob 2721 to the gear member 2723. The gear member 2723 meshes with the toothed post 2705 to drive the toothed post 2705 to slide along the third sliding slot 234 when the knob 2721 is rotated.

The restricting member 29 is fixed to the second support member 27 to restrict the adjusting assembly 27 from moving away from the second support member 23. The restricting member 29 is substantially rectangular and includes an engaging surface 290 corresponding to the assembly surface 230 of the second support member 23. The engaging surface 290 defines a receiving slot 292 for rotatably receiving the shaft 2722 and the gear member 2723.

In assembly, the protrusions 218 are received in the corresponding opening 212 by shafts 214 being received in the corresponding blind hole 219, thus the base 215 is pivotably connected to the main body 210. The sliding member 270 is mounted to the second support member 23 with the extendable leg 2701, the connection post 2703, and the toothed post 2705 being respectively received in the first sliding slot 232, the second sliding slot 233, and the third slot 234. The driving member 272 is connected to the sliding member 270 with the gear member 2723 meshing with the toothed surface 2707. The restricting member 29 is mounted to the second support member 23 with the engaging surface 290 abutting the assembly surface 230 and the receiving slot 292 receiving the gear member 2723 and the connection shaft 2722 therein.

To use the electronic device 1, the electronic device 1 can be located on the base 215 and received in the clearance defined between the contacting surface 211 and the block 217. In this state, the electronic device 1 can be adjustably standing upright on a horizontal surface to offer a good viewing angle to the user, and the extendable legs 2701 are completely received in the corresponding first slots 232.

When the viewing angle of the electronic device 1 needs to be adjusted, the knob 2721 is rotated in a first direction or in a second direction reverse to the first direction, and each extendable leg 2701 is driven to slide out of or slide into the second support member 23. As a result, the length of the part of each extendable leg 2701 extending out of the second support member 23 is changeable, the distance between the side wall 231 and a support surface is also changed, and the electronic device 1 can be viewed from different angles. When the connection post 2703 slides in the second sliding slot 233 to abut a slot wall (not labeled) which partially surrounds the second sliding slot 233 and is adjacent to the sidewall 231, the extendable legs 2701 are restricted from further sliding relative to the second support member 23, and the viewing angle of the electronic device 1 is thereby set.

It is to be understood, however, that even though information and the advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. A support mechanism for supporting an electronic device on a support surface, comprising:
a first support member for supporting the electronic device;
a second support member connected to the first support member for supporting the first support member; and
an adjusting assembly secured to the second support member and used for adjusting the height of the second support member relative to the support surface to adjust a viewing angle of the electronic device.

2. The support mechanism as claimed in claim 1, wherein the adjusting assembly comprises a sliding member, the sliding member is capable of sliding relative to the second support member to adjust the height of the second support member relative to the support surface, whereby the viewing angle of the electronic device is adjusted.

3. The support mechanism as claimed in claim 2, wherein the sliding member is capable of sliding relative to the second support member to partly extend out of the second support member, when the sliding member sliding relative to the second support member, the part of the sliding member extending out of the second support member to the support surface is adjustable.

4. The support mechanism as claimed in claim 1, wherein the second support member integrally extends from the first support member, and forms an angle therebetween.

5. The support mechanism as claimed in claim 1, wherein the first support member comprises a main body capable of abutting to aback portion of the electronic device and a base connected to the main body capable of abutting to a bottom portion of the electronic device.

6. The support mechanism as claimed in claim 5, wherein the base is capable of rotating relative to the main body.

7. The support mechanism as claimed in claim 6, wherein the base comprises a seat for supporting the electronic device and a block protruding from the seat, the block cooperates with the main body to define a clearance for holding the electronic device.

8. The support mechanism as claimed in claim 3, wherein the adjusting assembly further comprises a driving member, the driving member is operatively capable of driving the sliding member to partly extend out of the second support member.

9. The support mechanism as claimed in claim 8, wherein the sliding member comprises a toothed post, the driving member comprises a gear member meshing with the toothed post for driving the toothed post to slide relative to the second support member.

10. The support mechanism as claimed in claim 9, wherein the sliding member further comprises two extendable legs, the extendable legs are capable of being driven to slide relative to the second support member as the toothed post slides relative to the second support member.

11. The support mechanism as claimed in claim 10, wherein the sliding member further comprises a connection post connecting the extendable legs and the toothed post, the connection post engages with the second support member to restrict the extendable legs from further sliding relative to the second support member after the distance between the second support member and the support surface reaches a predetermined value.

12. The support mechanism as claimed in claim 9, wherein the support mechanism further comprises a restricting member connected to the second support member for preventing the driving member from moving away from the second support member.

13. The support mechanism as claimed in claim 12, wherein the restricting member defines a receiving slot for receiving the gear member for preventing the gear member from sliding together with the sliding member.

14. A support mechanism for supporting an electronic device on a support surface, comprising:
a first support member standing on the support surface and forming an angle therebetween;
a second support member connected to the first support member for supporting the first support member; and
an adjusting assembly secured to the second support member and used for adjusting the angle formed between the first support member and the support surface to adjust a viewing angle of the electronic device.

15. The support mechanism as claimed in claim 14, wherein the adjusting assembly comprises a sliding member slidably connected to the second support member to partly extend out of the second support member to adjust the height of the second support member and further to adjust the angle formed between the first support member and the support surface.

16. The support mechanism as claimed in claim 15, wherein the adjusting assembly further comprises a driving member engaging with the sliding member to drive the sliding member to slide relative to the second support member.

17. The support mechanism as claimed in claim 16, wherein the sliding member comprises two extendable legs and a connection post connecting the two extendable legs, each extendable leg is capable of sliding relative to the second support member to partly extend out of the second support member, the connection post is engageable with the second support member to restrict each extendable leg from sliding further after the height of the second support member reaches a predetermined value.

18. The support mechanism as claimed in claim 14, wherein the first support member comprises a main body capable of abutting a back portion of the electronic device and a base rotatably connected to the main body capable of supporting the electronic device and preventing the electronic device from sliding relative to the main body.

19. The support mechanism as claimed in claim 16, wherein the support mechanism further comprises a restricting member connected to the second support member for preventing the driving member from moving away from the second support member.
